(19) United States
(12) Patent Application Publication
(10) Pub. No.: US 2024/0161780 A1
(43) Pub. Date: May 16, 2024

(54) FASTENING ASSEMBLY WITH DETACHABLE LOCK PIN AND ENGAGING MEMBER

(71) Applicant: ENTEGRIS, INC., Billerica, MA (US)

(72) Inventors: Sin Ghun Lim, Butterworth (MY); Gian Ping Chua, Kulim (MY)

(21) Appl. No.: 18/511,579

(22) Filed: Nov. 16, 2023

Related U.S. Application Data
(60) Provisional application No. 63/425,918, filed on Nov. 16, 2022.

(51) Int. Cl. G11B 23/023; B65D 25/20; B65D 25/28

(52) U.S. Cl. CPC G11B 23/023; B65D 25/205; B65D 25/2802; B65D 2313/00

(57) ABSTRACT

A lock pin and an engagement member are provided to join articles. The lock pin includes a head portion, a neck portion and a base portion. The head portion is located above the second member and having a lower surface. The neck portion is connected at an upper end thereof to a lower surface of the head portion, wherein a width of the neck portion is smaller than a width of the lower surface of the head portion. The base portion is located in the first bore and connected to a lower end of the neck portion that is opposite to the upper end. The engaging member surrounds the neck portion and is sandwiched between the lower surface of the head portion and a surface of an article to which the lock pin is connected.

### FIELD

The present disclosure is generally directed to a fastening assembly for fastening a first article to a second article, and more particularly to a fastening assembly which can be quickly and easily assembled and disassembled to the articles.

### BACKGROUND

In the past, one common method to join an article to the other one is using an ultrasonic welding operation. However, weld quality of the ultrasonic welding operation is a major concern for a variety of manufacturing settings. Insufficient weld quality can lead to part failure and safety concerns. In addition, the ultrasonic welding method may not be applied to articles with irregular geometrical shape (such as curved surface) or to articles having welding spots which are located within a channel having a deep and narrow profile. Moreover, once articles are connected together by welds, procedures for undoing welding are complex and time-consuming.

### SUMMARY

According to some embodiments of the present invention a container is provided. The container includes an outer housing, a lock pin, an engaging member, and an accessory. The outer housing has at least one bore formed on a side wall of the outer housing. The lock pin includes a head portion, a neck portion and a base portion. The head portion is located an interior space of the outer housing and has a lower surface. The neck portion is connected at an upper end thereof to a lower surface of the head portion. A width of the neck portion is smaller than a width of the lower surface of the head portion. The base portion is located in the bore and connected to a lower end of the neck portion that is opposite to the upper end. The engaging member surrounds the neck portion and is sandwiched between the lower surface of the head portion and an inner surface of the side wall. The accessory is connected to the base portion so that the accessory is fixed to the outer housing via the lock pin and the engaging member.

According to some other embodiments of the present invention a fastening assembly is provided. The fastening assembly includes a first member, a second member, a lock pin and an engaging member. The first member has a first bore, and the second member is positioned on the first member and has a second bore aligning with the first bore. The lock pin includes a head portion, a neck portion and a base portion. The head portion is located above the second member and has a lower surface. The neck portion is connected at an upper end thereof to a lower surface of the head portion. A width of the neck portion is smaller than a width of the lower surface of the head portion. The base portion is located in the first bore and connected to a lower end of the neck portion that is opposite to the upper end. The engaging member surrounds the neck portion and is sandwiched between the lower surface of the head portion and an upper surface of the second member.

### BRIEF DESCRIPTION OF THE DRAWINGS

In the detailed description that follows, embodiments are described as illustrations only since various changes and modifications will become apparent to those skilled in the art from the following detailed description. The use of the same reference numbers in different figures indicates similar or identical items.

FIG. 1 is a schematic view of a container, in accordance with some embodiments of the present disclosure.

FIG. 2 is a schematic view of a lock pin and an accessory, such as handle, of the container of FIG. 1.

FIG. 3 is a schematic cross-sectional view showing an assembly process of the container of FIG. 1.

FIG. 4 is a schematic cross-sectional view of partial elements of the container of FIG. 1 as the lock pin being held by an engagement member.

FIG. 5 is a schematic view of a lock pin and an accessory, such as handle, in accordance with some embodiments of the present disclosure.

FIG. 6 is a schematic view of a lock pin and an accessory, such as handle, in accordance with some embodiments of the present disclosure.

FIG. 7 is a schematic cross-sectional view of a fastening assembly, in accordance with some embodiments of the present disclosure.

FIG. 8 is a schematic view of a lock pin, in accordance with some embodiments of the present disclosure.

FIG. 9 is a schematic cross-sectional view of a fastening assembly, in accordance with some embodiments of the present disclosure.

FIG. 10 is a schematic cross-sectional view of a fastening assembly, in accordance with some embodiments of the present disclosure.

FIG. 11 is a schematic cross-sectional view of a fastening assembly, in accordance with some embodiments of the present disclosure.

FIG. 12 is a schematic cross-sectional view of a fastening assembly, in accordance with some embodiments of the present disclosure.

### DETAILED DESCRIPTION

In the following detailed description, reference is made to the accompanying drawings, which form a part of the description. In the drawings, similar symbols typically identify similar components, unless the context dictates otherwise. Furthermore, unless otherwise noted, the description of each successive drawing may reference features from one or more of the previous drawings to provide a clearer context and a more substantive explanation of the current example embodiment. Still, the example embodiments described in the detailed description, drawings, and claims are not intended to be limiting. Other embodiments may be utilized, and other changes may be made, without departing from the spirit or scope of the subject matter presented herein. It will be readily understood that the aspects of the present disclosure, as generally described herein and illustrated in the drawings, may be arranged, substituted, combined, separated, and designed in a wide variety of different configurations, all of which are explicitly contemplated herein.

Spatially relative terms, such as “beneath,” “below,” “lower,” “above,” “over,” “upper,” “on,” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

As used herein, the terms such as “first,” “second” and “third” describe various elements, components, regions, layers and/or sections, these elements, components, regions, layers and/or sections should not be limited by these terms. These terms may only be used to distinguish one element, component, region, layer or section from another. The terms such as “first,” “second” and “third” when used herein do not imply a sequence or order unless clearly indicated by the context.

As used herein, the terms “approximately,” “substantially,” “substantial” and “about” are used to describe and account for small variations. When used in conjunction with an event or circumstance, the terms can refer to instances in which the event or circumstance occurs precisely as well as instances in which the event or circumstance occurs to a close approximation.

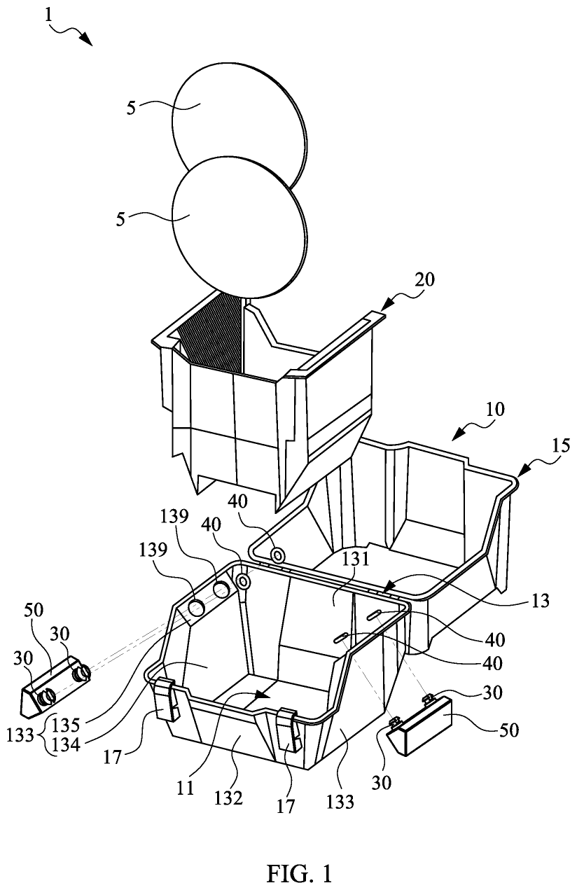

FIG. 1 is a schematic view of a container 1, in accordance with some embodiments of the present disclosure. In some embodiments, the container 1 includes an outer housing 10, an inner cassette 20, and a number of lock pins and engaging members, such as four lock pins 30 and four engaging members 40, and a number of accessories, such as two accessories 50. In one exemplary embodiment, the container 1 is used to receive multiple semiconductor wafers 5.

In said exemplary embodiment, semiconductor wafers 5 are arranged in slots formed in the inner cassette 20, and the inner cassette 20 along with the semiconductor wafers 5 can be removably received in an interior space 11 formed within the outer housing 10 for storage purpose. The inner cassette can subsequently be covered by the upper lid 15 of the container 1.

In some embodiments, the outer housing 10 includes a lower body 13 and an upper lid 15. The upper lid 15 is pivotally connected to an upper edge of a rear wall 131 of the lower body 13 and is selectively positioned in an open state (FIG. 1) and a closed state. In the closed state, the upper lid 15 fully covers the interior space 11 so as to keep the interior space 11 of the outer container 10 secluded from the surroundings. One or more lock members 17 may be connected to an upper edge of a front wall 132 of the lower body 13. The lock members 17 are used to fasten the upper lid 15 in the closed state, so as to prevent the upper lid 15 from being opened.

As shown in FIG. 1, the lower body 13 further includes two lateral walls 133. The two lateral walls 133 each connect the rear wall 131 to the front wall 132 and include a lower vertical segment 134 and an upper inclined segment 135. The upper inclined segment 135 extends upward and outward from the lower vertical segment 134 and is inclined relative to the lower vertical segment 134.

In some embodiments, two bores 139 are formed in each of the upper inclined segments 135. The bores 139 may be formed during a molding process of the outer housing 10. Alternatively, the bores 139 may be formed by drilling a circular hole at the upper inclined segments 135. It would be appreciated that the number of the bores and the positions of the bores may be changed according to actual needs, and should be not limited to the present embodiments.

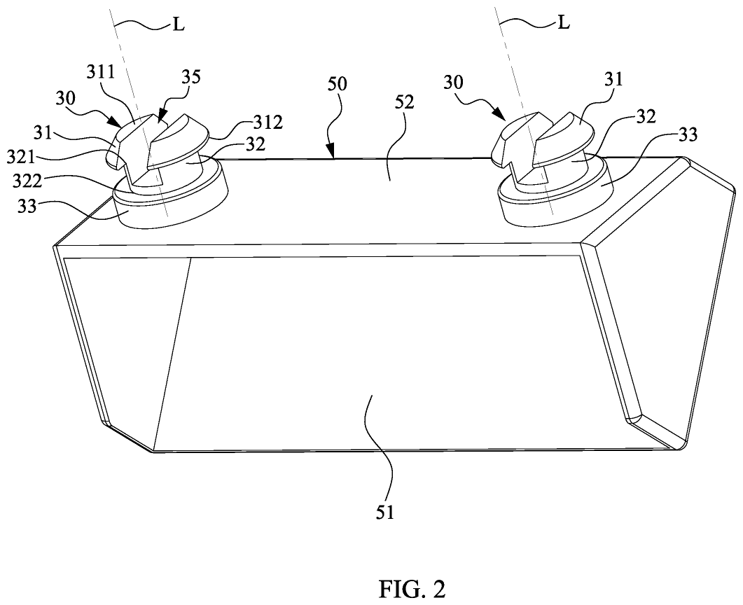

FIG. 2 is a schematic view of the lock pins 30 and the accessory 50 of the container of FIG. 1. In some embodiments, the accessory 50 is a handle and includes a gripping portion 51 and a connecting portion 52. The connecting portion 52 has a rectangular plate shape, and the gripping portion 51 is connected to the connecting portion 52 and is formed so as to allow the accessory 50 to be grasped and manipulated by hand. With such handle, it would be relatively easy for personnel to manually transport the container 1 (FIG. 1) loaded with semiconductor wafers 5 as such container is often around weigh 20 pounds.

In some embodiments, two lock pins 30 are connected to a rear surface of the connecting portion 52. Each of the lock pins 30 includes a head portion 31, a neck portion 32 and a base portion 33. The head portion 31, the neck portion 32 and a base portion 33 are sequentially arranged along a longitudinal axis L of the lock pin 30.

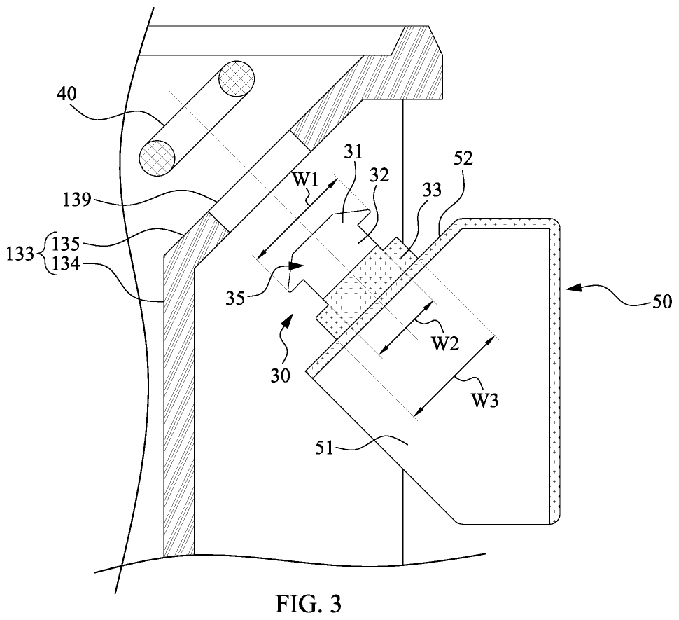

The had portion 31 has an upper surface 311, at an end of the lock pin 30 and a lower surface 312 opposite to the upper surface 311. The head portion 31 has a frustum shape tapering away from the neck portion 32. The neck portion 32 is connected at an upper end 321 thereof to the lower surface 312 of the head portion 31. The neck portion 32 has a cylinder shape with a second width W2 (FIG. 3), which is smaller than a first width W1 (FIG. 3) of the lower surface 312 of the head portion 31. The base portion 33 is connected to a lower end 322 of the neck portion 32. The base portion 33 may have a third width W3 (FIG. 3) that is substantially equal to the first width W1 of the head portion 31. The lock pin 30 is connected to the connecting portion 52 of the accessory 50 by the base portion 33. The lock pin 30 may be formed integrally with the connecting portion 52 of the accessory 50 by a molding process.

As shown in FIG. 2, a slot 35 is formed in the head portion 31 and the neck portion 32, and the slot 35 extends across in a direction that is perpendicular to a longitudinal axis L of the lock pin 30 with its two ends connects with a lateral surface of the lock pin 30. In some embodiments, the depth of the slot 35 is smaller than a sum of a height of the head portion 31 and a height of the neck portion 32. That is, a bottom of the slot 35 is away from the base portion 33. The slot 35 allows each half of the head portion 31 along with the neck portion 32 to be bent toward each other as a compression force is applied to the lock pin 30. However, it will be appreciated that many variations and modifications can be made to embodiments of the disclosure. In another embodiment, the depth of the slot 35 is equal to a sum of a height of the head portion 31 and a height of the neck portion 32. That is, the head portion 31 and the neck portion 32 are equally divided into two parts. In still another embodiment, the slot 35 is omitted, and the lock pin may be formed with a resilient materiel.

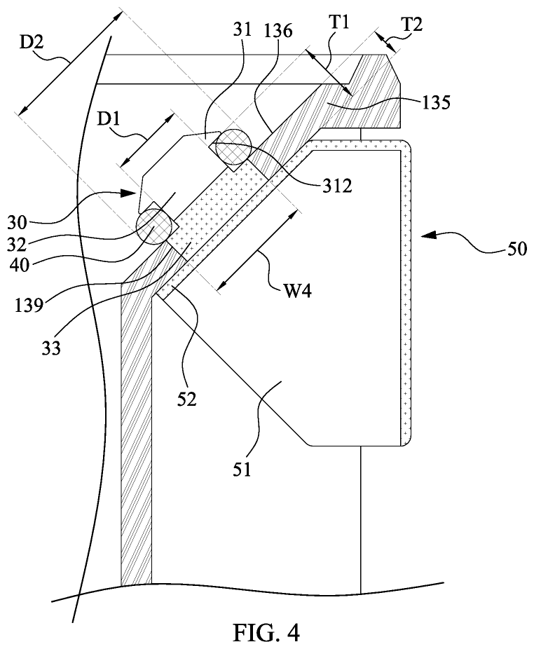

Referring FIG. 3, in some embodiments, the engaging member 40 is an O-ring, which is made of elastomer type of plastic. The material of the engaging member 40 may be selected so that it possesses excellent corrosion resistance and rust free advantage and is suitable in high humanity environment usage. In some embodiments, the inner diameter D1 (FIG. 4) of the engaging member 40 is slightly or substantially equal to the second width W2 of the neck portion 32. In addition, the outer diameter D2 (FIG. 4) of the engaging member 40 is greater than the first width W1 of the lower surface 312 of the head portion 31 and is greater than a width W4 of the bore 139. For example, the outer diameter D2 (FIG. 4) of the engaging member 40 is approximately about 3 mm to about 4 mm larger than the width W4 of the bore 139.

To fix the accessory 50 to the outer housing 10, the two lock pins 30 are firstly inserted into the bores 139 formed on the upper inclined segments 135 of the lower body 13. The insertion of the lock pin 30 is stopped when the connection portion 52 of the accessory 50 is abutted against an outer surface of the upper inclined segments 135. When the lock pin 30 is fully inserted into the bore 139, the head portion 31 is located inside the interior space 11 (FIG. 1) of the container 1, and the base portion 33 is positioned in the bore 139. In some embodiments, as shown in FIG. 4, a height of the base portion 33 is substantially equal to a thickness T2 of the upper inclined segments 135, so that an upper surface of the base portion 33 and the inner surface 136 of the upper inclined segments 135 are located at the same plane.

After the insertion of the lock pin 30 to the bore 139, the engaging member 40 is connected to the lock pin 30. According to some embodiments of present disclosure, the process for connecting the engaging member 40 to the lock pin 30 including: attaching the engaging member 40 to the head portion 31 of the lock pin 30; applying a thrust to the engaging member 40 to make the halves of the head portion 31, which are divided by the slot 35, be compressed thereby leading a reduction in a width of the head portion 31; moving the engaging member 40 to pass through the lower surface 312 of the head portion 31; and placing the engaging member 40 between the lower surface 312 of the head portion 31 and the inner surface 136 of the upper inclined segments 135. It would be appreciated that the frustum shape of head portion 31 would advantageously reduce the resistance during the movement of the engaging member 40 passing through the head portion 31.

With reference to FIG. 4, after the engaging member 40 is placed between the lower surface 312 of the head portion and the inner surface 136 of the upper inclined segments 135, the engaging member 40 is sandwiched and compressed by the lower surface 312 and the inner surface 136. Due to its resilient nature and because a thickness of the engaging member 40 is slightly greater than a width of a gap formed between the lower surface 312 and the inner surface 136, the engaging member 40 is slightly deformed thereby providing a stopping and holding force to the lock pin 30 to prevent the lock pin 30 from falling out of the bore 139. As shown in FIG. 4, the width of the gap formed between the lower surface 312 and the inner surface 136 may be equal to a difference between a thickness T1 of the neck portion 32 and the base portion 33 and the thickness T2 of the upper inclined segments 135. In one exemplary embodiment, the thickness of the engaging member 40 is approximately 3 mm, and the width of the gap is less than 3 mm. However, the dimension of the engaging member 40 should not be limited to the above embodiments, and might vary according to materials of the engaging member 40.

It is appreciated that since the engaging member 40 provides flexibility to accommodate part-to-part stack-up tolerance, the lock pin 30 can be efficiently attached to the outer housing 10 even though the lock pin 30 is not fully inserted into the bore 139 or is positioned inclined relative to a center axis of the bore 139. Therefore, the accessory 50 is firmly attached to the outer housing 10. In cases where the accessory 50 is a handle with two lock pins 30 attaching to the outer housing 10 as shown in FIG. 1, the handle exhibits a high load holding capability allowing a 20 kg static load during a load holding test.

In cases where the engaging member 40 is an O-ring, the engaging member 40 also work as a seal for the bore 139 surrounding the neck portion 32. In addition, the O-ring may provide dampening/shock absorbent to reduce vibration between storage box and handle and may avoid or reduce rattling noises between the lock pins 30 and/or the accessory 50 and the outer housing 10. Therefore, embodiments of present disclosure are suitable to be used in machinery movement parts, while at the same time keep the lock pin from loosening during the service time or during vibration occurs.

Method of removing the lock pin 30 from the outer housing 10 is described as follows. To remove the lock pin 30, an operator may compress the head portion 31 of the lock pin 30 to move halves of the head portion 31, which are divided by the slot 35, toward each other, and then remove the engaging member 40 from the lock pin 30. After the removal of the engaging member 40, the lock pin 30 is free from being detached from outer housing 10. Since the lock pin 30 can be easily and readily assembled to and disassembled from the outer housing 10, the accessories 50 with different functions can be substituted as demands. In addition, the accessories 50 may be easily disassembled for cleaning and/or replacement for maintenance.

It will be appreciated that the present disclosure is not limited to these particular examples mentioned above. In one exemplary embodiment, different from the molded handle as shown in FIG. 2, a gripping member, such as a rope or the like, may be fasten to the outer housing 10 via the two lock pins 30 to enable the operator to manually carry the container 1 or to enable a robot to automatically carry the container. Moreover, the accessory 50 may be a colored ID tag, an ID card, a card holder, a RFID holder, or any other articles which can be used to identify the outer housing 10.

The arrangements of the bores 139 and the lock pins 30 may be varied. For example, the numbers of the bores 139 formed on the outer housing 10 and the number of the lock pins 30 may be varied according to demands. Furthermore, the bore(s) 139 may be formed in any other suitable positions on the outer housing 10 as long as the lock pin 30 can be firmly attached thereto. Thanks to the advantage of flexibility, the application of the lock pin 30 and the engaging member 40 can be realized, according to any particular demands, in any commercially available containers by forming the bore(s) 139 therein.

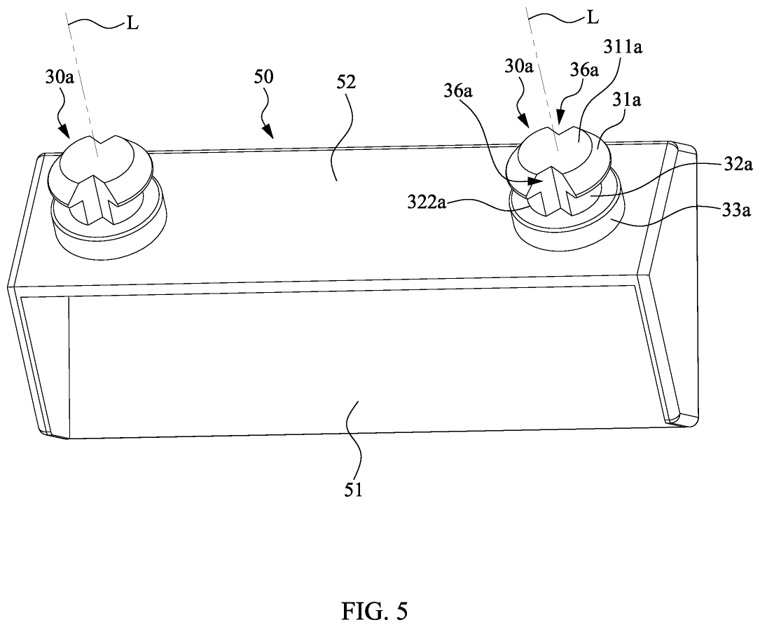

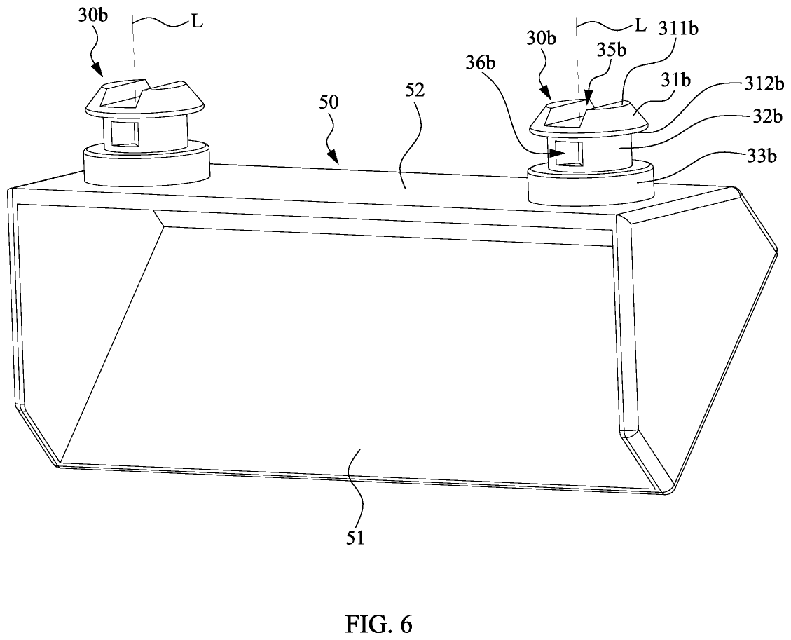

Referring FIGS. 5 and 6, different configurations of the lock pin are provided, in accordance with some embodiments of the present disclosure.

In the embodiment of FIG. 5, the lock pin 30a includes a head portion 31a, a neck portion 32a, and a base portion 33a. The head portion 31a, the neck portion 32a and the base portion 33a are sequentially arranged along a longitudinal axis L of the lock pin 30a. Differences between the lock pin 30a and the lock pin 30 shown in FIG. 2 include the slot 35 of the lock pin 30 being omitted and two notches 36a being formed at two opposite sides of the lock pin 30a. The two notches 36a may be each formed with a V-shape or a U-shape and are formed at the lateral surface of the lock pin 30a corresponding to the head portion 31a and the neck portion 32a.

In some embodiments, as show in FIG. 5, each of the notches 36a extends, in a direction that is parallel to the longitudinal axis L of the lock pin 30a, from an upper surface 311a of the head portion 31a all the way to the lower end 322a of the neck portion 32a that is connected to the base portion 33a. The notches 36a may not only facilitate the assembly and disassembly process of the lock pin 30a and an engaging member (such as engaging member 40 shown in FIG. 1), it also prevents a sink mark from being deformed during a molding process. The sink mark may formed when the internal material, such as plastic or the like, on a thick section of a molded part cools down slower than the material around which located near the outside. When the surrounding material cools down and solidified, the molten internal material will create sink mark on the surface of the molded part which is aesthetically unpleasant.

In the embodiment of FIG. 6, the lock pin 30b includes a head portion 31b, a neck portion 32b, and a base portion 33b. The head portion 31b, the neck portion 32b and the base portion 33b are sequentially arranged along a longitudinal axis L of the lock pin 30b. Differences between the lock pin 30b and the lock pin 30 as shown in FIG. 2 include the slot 35 of the lock pin 30 being replaced with a slot 35b and two notches 36b being formed at two opposite sides of the lock pin 30b. The slot 35b is recessed into an upper surface 321b of the head portion 32b, but is distant from a lower surface 312b of the head portion 31b. The two notches 36b may be each formed with a V-shape or a U-shape and are formed at the lateral surface of the lock pin 30b corresponding to the neck portion 32b. The slot 35b may facilitate the assembly and disassembly process of the lock pin 30b and an engaging member (such as engaging member 40 shown in FIG. 1), and the notches 36b may prevent a sink mark from being deformed during a molding process of the lock pin 30b.

In addition to be used in the container 1 as shown in FIG. 1, the lock pin 30 and the engaging member 40 can also be used to joint two articles for different purposes. Various embodiments are provided as follows:

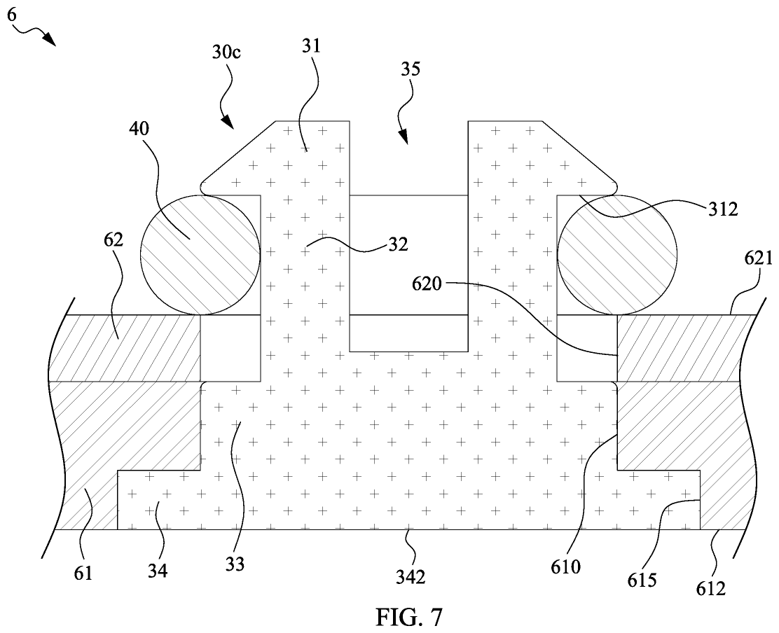

FIG. 7 is a cross-sectional view of a fastening assembly 6, in accordance with some embodiments of the present disclosure. The fastening assembly 6 includes a first member 61, a second member 62, a lock pin 30c and the engaging member 40. The first and second members 61 and 62 may be outer chassis of two devices. The first member 61 has a bore 610, and the second member 62 has a bore 620. The bores 610 and 620 both have a circular shape or a polygon shape. One of the bores 610 and 620 has a groove formed at an inner wall thereof. For example, a groove 615 is formed at an inner wall of the bore 610 and is located immediately adjacent to a lower surface 612 that is away from the second member 62.

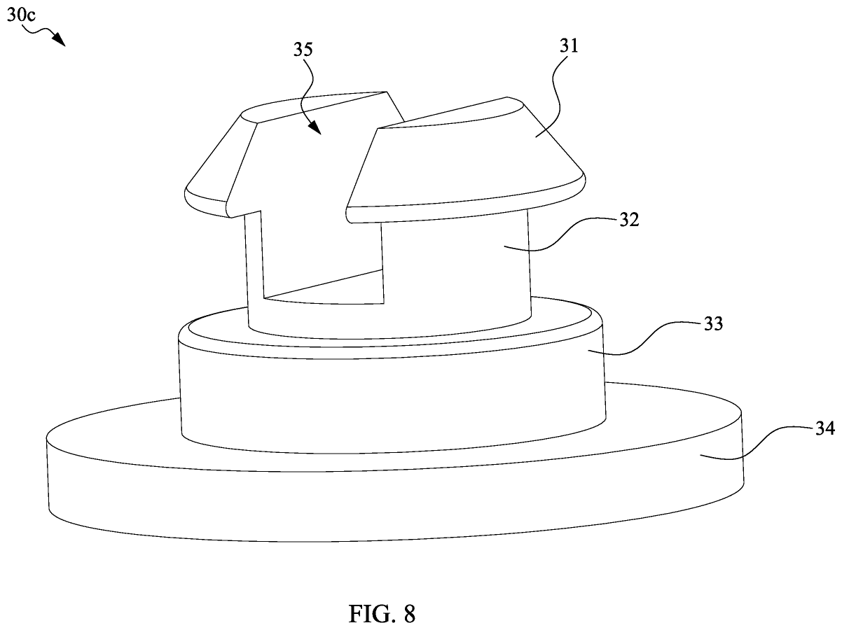

With reference to FIG. 8, the lock pin 30c has a configuration that is similar to lock pin 30 as shown in FIG. 2 but it further includes an extended portion 34. The extended portion 34 is formed at a bottom of the base portion 33 and has a greater width than the base portion 33. In some embodiments, a width and a thickness of the extended portion 34 is conformal with that of the groove 615 with which it is to be engaged. In some other embodiments, the slot 35 of the lock pin 30c can be replaced by the slot 35b shown in FIG. 5. Additionally or alternatively, two notches as shown in FIG. 6 maybe formed in the lock pin 30c.

To assembly the first member 61 and the second member 62, the first and second members 61 and 62 are overlapped to align the bores 610 and 620, and then the head portion 31 of the lock pin 30c is moved to sequentially pass through the bore 610 and the bore 620 so as to place the lock pin 30c into the bores 610 and 620. When the lock pin 30c is placed into the bores 610 and 620, the head portion 31 is located above an upper surface 621 of the second member 62, the base portion 33 is fitted with the bore 610, and the extended portion 34 is fitted with the groove 615.

After the lock pin 30c is placed into the bores 610 and 620, the engaging member 40 is connected to the lock pin 30c by performing operations similar to those to connect the engaging member 40 to the lock pin 30 mentioned above. When the engaging member 40 is connected to the lock pin 30c, the engaging member 40 is sandwiched and compressed between the lower surface 312 of the head portion 31 and the upper surface 621 of the second member 62. As a result, a stopping and holding force to the lock pin 30c to prevent the first and second member 61 and 62 from being disengaged is provided by the engaging member 40.

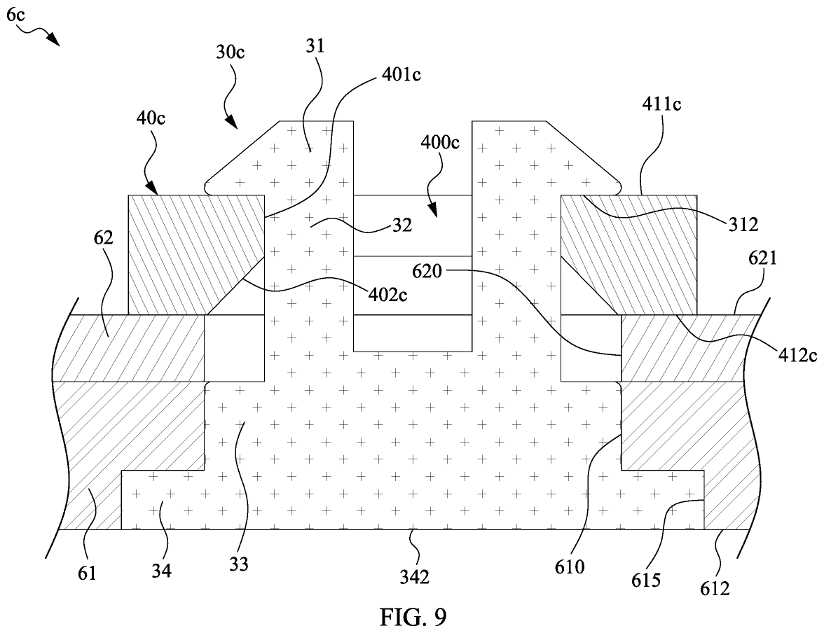

FIG. 9 is a cross-sectional view of a fastening assembly 6c, in accordance with some embodiments of the present disclosure. The components in FIG. 9 that use the same reference numerals as the components of FIG. 8 refer to the same components or equivalent components thereof. For the sake of brevity, it will not be repeated here. Differences between the fastening assembly 6 and the fastening assembly 6c include the engaging member 40 being replaced with an engaging member 40c.

The engaging member 40c is a pad with particular dimensions suitable for the fastening assembly 6c. In some embodiments, the engaging member 40c is a plastic molded component and is made of moldable polymers material, such as polyurethane or the like. The outer profile of the engaging member 40c may be a circular shape, a rectangular shape or a polygon shape and is not limited to round shape only. A through hole 400c is formed in the engaging member 40c for allowing the lock pin 30c to pass therethrough. The through hole 400c has an upper inner wall 401c and a lower inner wall 402c. The upper inner wall 401c is connected and perpendicular to an upper surface 411c of the engaging member 40c, and the lower inner wall 402c is connected to a lower surface 412c of the engaging member 40c. In some embodiments, the lower inner wall 402c is inclined relative to the longitudinal axis of the lock pin 30c. The lower inner wall 402c which askew extends may facilitate the movement of the head portion 31 of the lock pin 30c passing through the engaging member 40c.

The engaging member 40c may have a geometric specification that is special for the application of the fastening assembly 6c. For example, a thickness of the engaging member 40c is substantially equal to a distant between the lower surface 312 and the upper surface 621 of the second member 62. Therefore, when fastening assembly 6c is assembled, the upper surface 411c and the lower surface 412c of the engaging member 40c are fitted with the lower surface 312 of the head portion 31 and the upper surface 621 of the second member 62, which may advantageously mitigate or avoid a shaking or vibration of the lock pin 30c during the operation of a system including the fastening assembly 6c. It is appreciated that the engaging member 40c can be used in the container 10 as a substitute for the engaging ember 40.

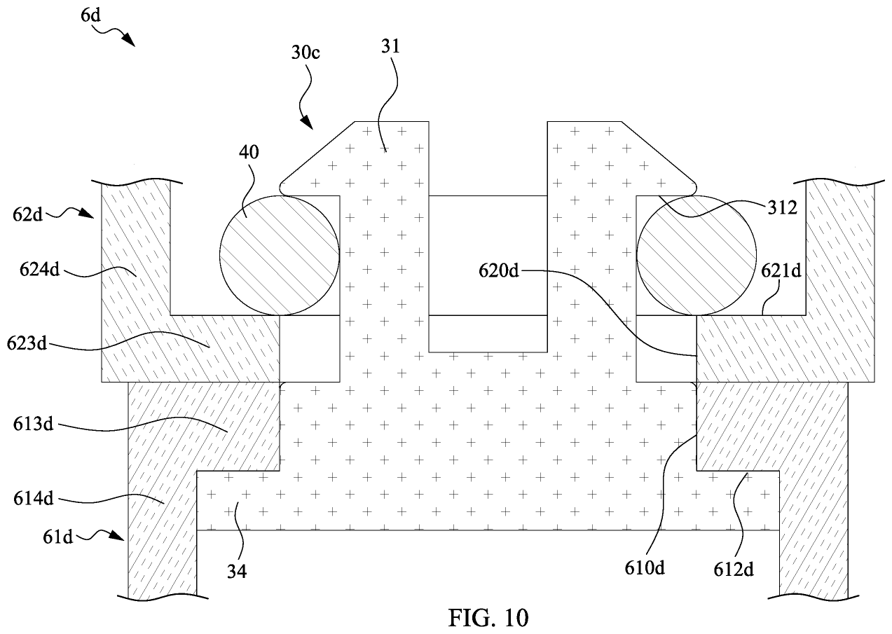

Embodiments of the fastening assembly of present disclosure can be applied to variable surface geometry adaptation with minimum working area/space required, and the articles connected by the lock pin and the engaging member may be formed with different materials, such as metal and plastic. Therefore, the fastening assembly can be extensively used to more applications as compared with conventional ultrasonic welding method. Exemplary embodiments are described below with references to FIGS. 10-12.

FIG. 10 shows a schematic cross-sectional view of a fastening assembly 6d in accordance with some embodiments of present disclosure, the lock pin 30c and the engaging member 40 are used to connect first and second members 61d and 62d. The first member 61d includes a bottom wall 613d and a side wall 614d, and a bore 610d is formed at the bottom wall 613d. The second member 62d includes a bottom wall 623d and a side wall 624d, and a bore 620d is formed at the bottom wall 623d. The bottom wall 613d and the bottom wall 623d are connected together through an assembling method that is similar to that employed in the embodiment with reference to FIGS. 3 and 4. After the assembly of the lock pin 30c and the engaging member 40, the engaging member 40 is sandwiched between the lower surface 312 and an upper surface 621d of the second member 62d, and the extended portion 34 of the lock pin 30c is engaged with a lower surface 612d of the bottom wall 613d.

In some embodiments, at least one of the first and second members 61d and 62d are parts with deep and narrow profile. For example, the bore 610d of the first member 61d is formed at a bottom of a void which has a relative height depth-to-width ratio. That is, a height of the side wall 614d is, for example, at least five time greater than a width of the bottom wall 613d.

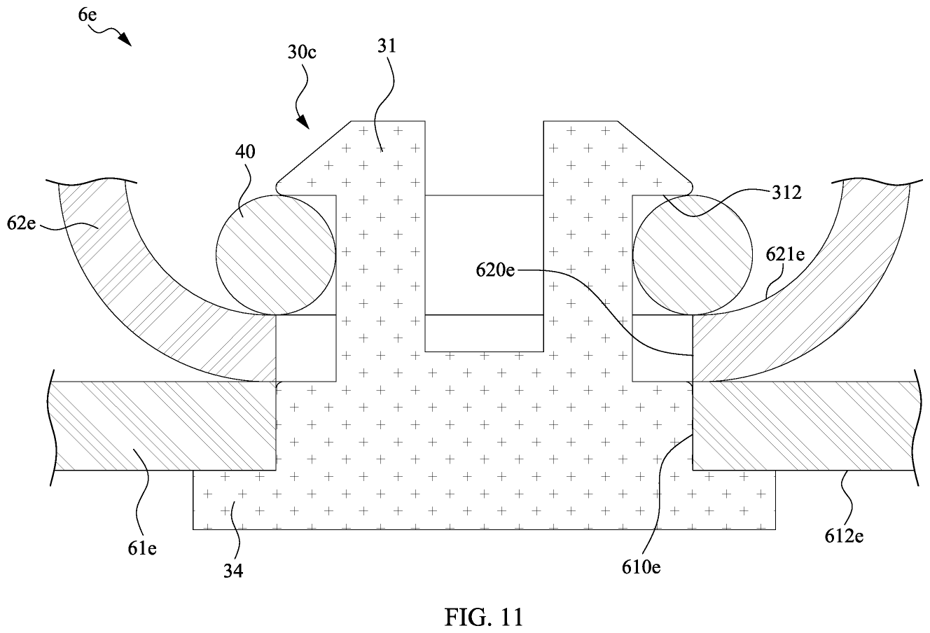

FIG. 11 shows a schematic cross-sectional view of a fastening assembly 6e in accordance with some embodiments of present disclosure, the lock pin 30c and the engaging member 40 are used to connect two first and second members 61e and 62e. The first member 61e is formed with a planar shape, and a bore 610e is formed at the first member 61e. The second member 62e is formed with a curved shape or a round shape, and a bore 620e is formed at the curved surface of the second member 62e. The first member 61e and the second member 62e are connected together through an assembling method that is similar to that employed in the embodiment with reference to FIGS. 3 and 4. After the assembly of the lock pin 30c and the engaging member 40, the engaging member 40 is sandwiched between the lower surface 312 and an upper surface 621e of the second member 62e, and the extended portion 34 of the lock pin 30c is engaged with a lower surface 612e of the first and second members 61e. Due to the pliable and compressible nature of the engaging member 40, the first and second members 61e and 62e can be stably and firmly connected despite the curvature surface of the second member 62e.

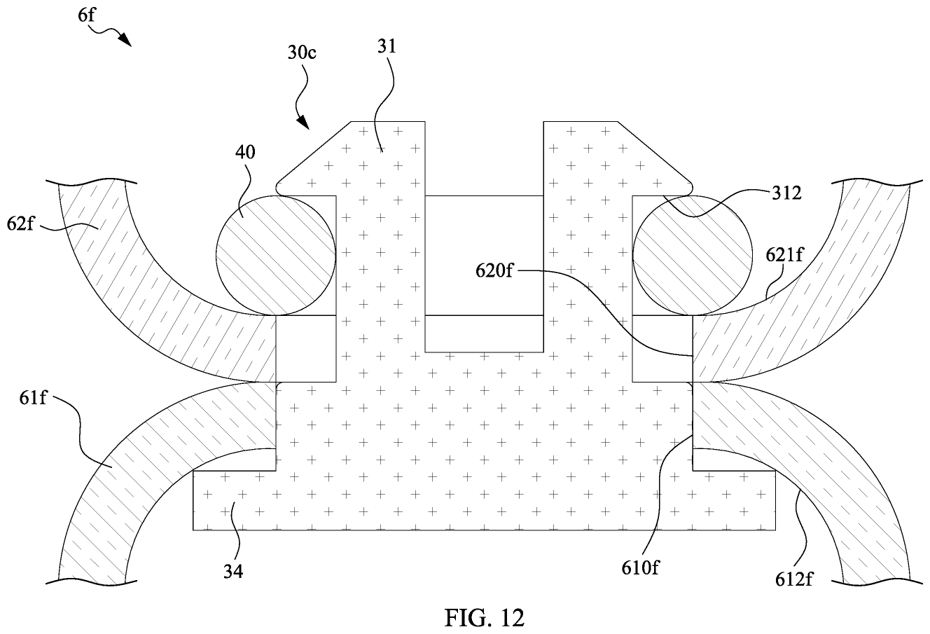

FIG. 12 shows a schematic cross-sectional view of a fastening assembly 6f in accordance with some embodiments of present disclosure, the lock pin 30c and the engaging member 40 are used to connect two first and second members 61f and 62f. The first and second members 61f and 62f are both formed with a curved shape or a round shape, and bores 610f and 620f are formed at the curved surface of the first and second members 61f and 62f. The first and second members 61f and the second member 62f are connected together through an assembling method that is similar to that employed in the embodiment with reference to FIGS. 3 and 4. After the assembly of the lock pin 30c and the engaging member 40, the engaging member 40 is sandwiched between the lower surface 312 and an upper surface 621f of the second member 62f, and the extended portion 34 of the lock pin 30c is engaged with a lower surface 612f of the first and second members 61f. Due to the pliable and compressible nature of the engaging member 40, the first and second members 61f and 62f can be stably and firmly connected despite the curvature surface of the second member 62f.

Embodiments of the present disclosure provide methods of assembling articles as a substitute for conventional ultrasonic welding or mechanical fastening method by using a lock pin and an engaging member. Since the lock pin and the engaging member for joining articles may be made of any suitable material and not limited to metallic material, and thus can be used in a stringent metal contamination environment. In addition, because the lock pin and the engaging member has a simple structure and assembly operation, no or simple tool is used during assembly and disassembly operation and maintenance requirements can be minimalized.

Aspect 1. A container, comprising:
an outer housing, having at least one bore formed on a side wall of the outer housing;
a lock pin, comprising:
   a head portion, located an interior space of the outer housing and having a lower surface;
   a neck portion, connected at an upper end thereof to a lower surface of the head portion, wherein a width of the neck portion is smaller than a width of the lower surface of the head portion; and
   a base portion, located in the bore and connected to a lower end of the neck portion that is opposite to the upper end;
an engaging member, surrounding the neck portion and being sandwiched between the lower surface of the head portion and an inner surface of the side wall; and
an accessory, connected to the base portion so that the accessory is fixed to the outer housing via the lock pin and the engaging member.

Aspect 2. The container of aspect 1, wherein a slot is formed in the head portion and at least a portion of the neck portion, and the slot extends across in a direction that is perpendicular to a longitudinal axis of the lock pin.

Aspect 3. The container of Aspect 1, wherein at least one notch is formed at a lateral surface of the lock pin.

Aspect 4. The container of Aspect 3, wherein the notch extends, in a direction that is parallel to a longitudinal axis of the lock pin, all the way from an upper surface of the head portion that is opposite to the lower surface to the neck portion.

Aspect 5. The container of Aspect 1, wherein the head portion is tapered in a direction that is away from the neck portion.

Aspect 6. The container of Aspect 1, wherein the engaging member has a tubular shape, and an outer diameter of the engaging member is greater than a diameter of the bore of the outer housing.

Aspect 7. The container of Aspect 1, wherein the engaging member has a plate shape, a through hole is formed in the engaging member for allowing the neck portion to pass therethrough, wherein the through hole comprises a lower inner wall intersecting with a lower surface of the engaging member, and the lower inner wall is inclined relative to a longitudinal axis of the lock pin.

Aspect 8. The container of Aspect 1, wherein the engaging member includes polymers material and is deformable as compressed by the lower surface of the head portion and the inner surface of the outer housing.

Aspect 9. The container of Aspect 1, further comprising an inner cassette positioned in the interior space of the outer housing for receiving at least one semiconductor wafer.

Aspect 10. The container of Aspect 1, wherein the accessory comprises a handle, a colored ID tag, an ID card, a card holder, or a RFID holder.

Aspect 11. A fastening assembly, comprising:
a first member having a first bore;
a second member positioned on the first member and having a second bore aligning with the first bore;
a lock pin, comprising:
   a head portion, located above the second member and having a lower surface;
   a neck portion, connected at an upper end thereof to a lower surface of the head portion, wherein a width of the neck portion is smaller than a width of the lower surface of the head portion; and
   a base portion, located in the first bore and connected to a lower end of the neck portion that is opposite to the upper end; and
an engaging member, surrounding the neck portion and being sandwiched between the lower surface of the head portion and an upper surface of the second member.

Aspect 12. The fastening assembly of Aspect 11, wherein a slot is formed in the head portion and at least a portion of the neck portion, the slot extends across in a direction that is perpendicular to a longitudinal axis of the lock pin.

Aspect 13. The fastening assembly of Aspect 11, wherein at least one notch is formed at a lateral surface of the lock pin.

Aspect 14. The fastening assembly of Aspect 11, wherein the head portion is tapered in a direction that is away from the neck portion.

Aspect 15. The fastening assembly of Aspect 11, wherein the engaging member has a tubular shape, and an outer diameter of the engaging member is greater than a diameter of the second bore.

Aspect 16. The fastening assembly of Aspect 11, wherein a through hole is formed in the engaging member for allowing the neck portion to pass therethrough, wherein the through hole comprises a lower inner wall intersecting with a lower surface of the engaging member, and the lower inner wall is inclined relative to a longitudinal axis of the lock pin.

Aspect 17. The fastening assembly of Aspect 11, wherein the engaging member includes polymers material and is deformable as compressed by the lower surface of the head portion and an upper surface of the second member.

Aspect 18. The fastening assembly of Aspect 11, wherein the lock pin further comprises an extended portion connected to a bottom of the base portion that is away from the neck portion, and a groove circumferentially extends around an inner wall of the first bore, the extended portion is received in the groove.

Aspect 19. The fastening assembly of Aspect 11, wherein the lock pin further comprises an extended portion connected to a bottom of the base portion that is away from the neck portion, and the extended portion is abutted against a lower surface of the first member.

Aspect 20. The fastening assembly of Aspect 11, wherein at least one of the first member and the second member has a curved surface, and the first bore or the second bore is formed at the curved surface.

The examples disclosed in this application are to be considered in all respects as illustrative and not limitative. The scope of the invention is indicated by the appended claims rather than by the foregoing description; and all changes which come within the meaning and range of equivalency of the claims are intended to be embraced therein.

The terminology used in this specification is intended to describe particular embodiments and is not intended to be limiting. The terms “a,” “an,” and “the” include the plural forms as well, unless clearly indicated otherwise. The terms “comprises” and/or “comprising,” when used in this specification, specify the presence of the stated features, integers, steps, operations, elements, and/or components, but do not preclude the presence or addition of one or more other features, integers, steps, operations, elements, and/or components.

With regard to the preceding description, it is to be understood that changes may be made in detail, especially in matters of the construction materials employed and the shape, size, and arrangement of parts without departing from the scope of the present disclosure. This specification and the embodiments described are exemplary only, with the true scope and spirit of the disclosure being indicated by the claims that follow.

What is claimed is:

1. A container, comprising:
an outer housing, having at least one bore formed on a side wall of the outer housing;
a lock pin, comprising:
a head portion, located an interior space of the outer housing and having a lower surface;
a neck portion, connected at an upper end thereof to a lower surface of the head portion, wherein a width of the neck portion is smaller than a width of the lower surface of the head portion; and
a base portion, located in the bore and connected to a lower end of the neck portion that is opposite to the upper end;
an engaging member, surrounding the neck portion and being sandwiched between the lower surface of the head portion and an inner surface of the side wall; and
an accessory, connected to the base portion so that the accessory is fixed to the outer housing via the lock pin and the engaging member.

2. The container of claim 1, wherein a slot is formed in the head portion and at least a portion of the neck portion, and the slot extends across in a direction that is perpendicular to a longitudinal axis of the lock pin.

3. The container of claim 1, wherein at least one notch is formed at a lateral surface of the lock pin.

4. The container of claim 3, wherein the notch extends, in a direction that is parallel to a longitudinal axis of the lock pin, all the way from an upper surface of the head portion that is opposite to the lower surface to the neck portion.

5. The container of claim 1, wherein the engaging member has a tubular shape, and an outer diameter of the engaging member is greater than a diameter of the bore of the outer housing.

6. The container of claim 1, wherein the engaging member has a plate shape, a through hole is formed in the engaging member for allowing the neck portion to pass therethrough, wherein the through hole comprises a lower inner wall intersecting with a lower surface of the engaging member, and the lower inner wall is inclined relative to a longitudinal axis of the lock pin.

7. The container of claim 1, further comprising an inner cassette positioned in the interior space of the outer housing for receiving at least one semiconductor wafer.

8. The container of claim 1, wherein the accessory comprises a handle, a colored ID tag, an ID card, a card holder, or a RFID holder.

9. A fastening assembly, comprising:
a first member having a first bore;
a second member positioned on the first member and having a second bore aligning with the first bore;
a lock pin, comprising:
a head portion, located above the second member and having a lower surface;
a neck portion, connected at an upper end thereof to a lower surface of the head portion, wherein a width of the neck portion is smaller than a width of the lower surface of the head portion; and
a base portion, located in the first bore and connected to a lower end of the neck portion that is opposite to the upper end; and
an engaging member, surrounding the neck portion and being sandwiched between the lower surface of the head portion and an upper surface of the second member.

10. The fastening assembly of claim 9, wherein a slot is formed in the head portion and at least a portion of the neck portion, the slot extends across in a direction that is perpendicular to a longitudinal axis of the lock pin.

11. The fastening assembly of claim 9, wherein at least one notch is formed at a lateral surface of the lock pin.

12. The fastening assembly of claim 9, wherein the head portion is tapered in a direction that is away from the neck portion.

13. The fastening assembly of claim 9, wherein the engaging member has a tubular shape, and an outer diameter of the engaging member is greater than a diameter of the second bore.

14. The fastening assembly of claim 9, wherein a through hole is formed in the engaging member for allowing the neck portion to pass therethrough, wherein the through hole comprises a lower inner wall intersecting with a lower surface of the engaging member, and the lower inner wall is inclined relative to a longitudinal axis of the lock pin.

15. The fastening assembly of claim 9, wherein the lock pin further comprises an extended portion connected to a bottom of the base portion that is away from the neck portion, and a groove circumferentially extends around an inner wall of the first bore, the extended portion is received in the groove.

16. The fastening assembly of claim 9, wherein the lock pin further comprises an extended portion connected to a bottom of the base portion that is away from the neck portion, and the extended portion is abutted against a lower surface of the first member.

17. The fastening assembly of claim 9, wherein at least one of the first member and the second member has a curved surface, and the first bore or the second bore is formed at the curved surface.

18. A container, comprising:
an outer housing;
an inner cassette removably received within an interior space of the outer housing;
at least one bore formed on a side wall of the outer housing;
at least one accessory fixed to the outer housing; and
one or more lock members locking the accessories to the outer housing, comprising:
a lock pin, comprising:
a head portion, located an interior space of the outer housing and having a lower surface;
a neck portion, connected at an upper end thereof to a lower surface of the head portion, wherein a width of the neck portion is smaller than a width of the lower surface of the head portion; and
a base portion, located in the bore and connected to a lower end of the neck portion that is opposite to the upper end wherein the base portion connects to the accessory to fix the accessory to the outer housing; and
an engaging member, surrounding the neck portion and being sandwiched between the lower surface of the head portion and an inner surface of the side wall.

19. The container of claim 18, wherein the inner cassette comprises a plurality of semiconductor wafer slots capable of removably receiving at least one wafer.

20. The container of claim 18, wherein the accessory comprises a handle, a colored ID tag, an ID card, a card holder, or a RFID holder.
